(19) United States
(12) Patent Application Publication
(10) Pub. No.: US 2004/0206307 A1
(43) Pub. Date: Oct. 21, 2004

(54) Method and system having at least one thermal transfer station for making OLED displays

(75) Inventors: Michael L. Boroson, Rochester, NY (US); Bradley A. Phillips, Honeoye Falls, NY (US); David B. Kay, Rochester, NY (US); Andrea S. Rivers, Bloomfield, NY (US); Mark D. Bedzyk, Pittsford, NY (US); Lee W. Tutt, Webster, NY (US); Myron W. Culver, Rochester, NY (US); Giana M. Phelan, Rochester, NY (US)

Correspondence Address: Thomas H. Close, Patent Legal Staff, Eastman Kodak Company, 343 State Street, Rochester, NY, 14650-2201, US

(73) Assignee: Eastman Kodak Company

(21) Appl. No.: 10/414,699

(22) Filed: Apr. 16, 2003

(51) Int. Cl. B05D 5/06; C23C 16/00

(52) U.S. Cl. 118/719; 427/66; 427/457

(57) ABSTRACT

Making an OLED device, in a controlled environment, includes positioning a substrate having an electrode in a first station and coating one or more first organic layer(s); using a robot to grasp and remove the substrate from the first station and positioning the coated substrate into a second station, with a donor element that includes emissive organic material; applying radiation to selectively transfer organic material from the donor element to the substrate to form an emissive layer; forming a second electrode in a third station; and controlling the atmosphere in the stations so that the water vapor partial pressure is less than 1 torr but greater than 0 torr, or the oxygen partial pressure is less than 1 torr but greater than 0 torr, or both the water vapor partial pressure and the oxygen partial pressure are respectively less than 1 torr but greater than 0 torr.

### CROSS REFERENCE TO RELATED APPLICATIONS

Reference is made to commonly assigned U.S. patent application Ser. No. 10/021,410, filed Dec. 12, 2001, entitled “Apparatus for Permitting Transfer of Organic Material From a Donor to Form a Layer in an OLED Device” by Bradley A. Phillips et al, U.S. patent application Ser. No. 10/141,587, filed May 8, 2002, entitled “In-Situ Method for Making OLED Devices That are Moisture or Oxygen-Sensitive” by Michael L. Boroson et al, U.S. patent application Ser. No. 10/211,213, filed Aug. 2, 2002, entitled “Laser Thermal Transfer From a Donor Element Containing a Hole-Transporting Layer” by Myron W. Culver et al, U.S. patent application Ser. No. 10/224,182 filed Aug. 20, 2002, entitled “Apparatus for Permitting Transfer of Organic Material From a Donor Web to Form a Layer in an OLED Device” by Bradley A. Phillips et al; the disclosures of which are incorporated herein by reference.

### FIELD OF THE INVENTION

The present invention relates to making organic light-emitting diode (OLED) displays having at least one station that uses thermal transfer.

### BACKGROUND OF THE INVENTION

OLED displays are one of the most recent flat panel display technologies and are predicted to overtake LCD display technology within the next decade. OLED displays offer brighter displays, significantly wider viewing angles, lower power requirements, and longer lifetimes than their LCD counterparts. OLED technology offers more display flexibility and alternatives to backlit LCD displays. For example, OLED displays may be made of thin, flexible materials that conform to any desired shape for specific applications. However, OLED displays and their components known as OLED structures, which constitute sub-pixels of the display, are more difficult and costly to manufacture than LCD displays. It is a continuing focus of the industry to increase throughput in an effort to lower the cost of OLED manufacturing.

Conventional OLED display devices are built on glass substrates in a manner such that a two-dimensional OLED array for image manifestation is formed. The basic OLED cell structure consists of a stack of thin organic layers sandwiched between one or more anode(s) and one or more metallic cathode(s). The organic layers typically comprise a hole transport layer (HTL), an emissive layer (EL), and an electron transport layer (ETL). When an appropriate voltage is applied to the cell, the injected holes and electrons recombine in the emissive layer near the EL-HTL interface to produce light (electroluminescence). In conventional OLED manufacturing, linear or point source vacuum deposition processes are used to deposit the organic materials on to the substrate.

The emissive layer within a color OLED display device most commonly includes three different types of fluorescent materials that are repeated through the emissive layer. Red, green, and blue regions, or subpixels, are formed throughout the emissive layer during the manufacturing process to provide a two-dimensional array of pixels. Each of the red, green, and blue subpixel sets undergoes a separate patterned deposition, for example, by evaporating a linear source through a shadow mask. Linear source vacuum deposition with shadow masking is a well-known technology, yet it is limited in the precision of its deposition pattern and in the pattern's fill factor or aperture ratio; thus, incorporating shadow masking into a manufacturing scheme limits the achievable sharpness and resolution of the resultant display. Radiation thermal transfer promises a more precise deposition pattern and higher aperture ratio; however, it has proved challenging to adapt radiation thermal transfer to a high throughput manufacturing line, which is necessary to warrant its use in the manufacture of cost-effective OLED display devices.

During radiation thermal transfer, a donor sheet having the desired organic material is typically placed into close proximity to the OLED substrate within a vacuum chamber. A radiation source impinges through a support that provides physical integrity to the donor sheet and is absorbed within a radiation-absorbing layer contained atop the support. The conversion of the radiation source's energy to heat transfers the organic material that forms the top layer of the donor sheet and thereby transfers the organic material in a desired subpixel pattern to the OLED substrate.

The combination of traditional linear source based deposition processes with radiation thermal transfer processes would allow the advantages of both processes to be applied to OLED manufacturing. However, OLED organics are particularly susceptible to damage from environmental exposure, especially to moisture, oxygen, and ultraviolet light. The challenge is to integrate the various processes in a way that is both cost effective and fully controls the environment of the OLED.

U.S. Pat. No. 6,485,884, entitled, “Method for patterning oriented materials for organic electronic displays and devices,” provides a method for patterning oriented materials to make OLED display devices, and also provides donor sheets for use with the method, as well as methods for making the donor sheets. However, the '884 patent fails to provide a system that enables radiation thermal transfer to be combined with more conventional deposition techniques, such as linear evaporation through a shadow mask, to form a manufacturing system that is scalable and capable of the throughput necessary to enable the cost-effective manufacture of OLED display devices.

### SUMMARY OF THE INVENTION

It is therefore an object of the present invention to provide a more effective way of making OLED displays.

This object is achieved in a method of making an OLED device comprising, in a controlled environment, the steps of:

a) positioning a substrate having an electrode in a first station and coating one or more first organic layer(s) over the substrate;

b) using a robot to grasp and remove the substrate from the first station and positioning the coated substrate into a second station, in material transferring relationship with a donor element that includes emissive organic material;

c) applying radiation to the donor element to selectively transfer organic material from the donor element to the substrate to form an emissive layer on the coated substrate;

d) forming a second electrode in a third station over the one or more second organic layers of the emissive coated substrate; and

e) controlling the atmosphere in the first, second, and third stations and in which the robot operates so that the water vapor partial pressure is less than 1 torr but greater than 0 torr, or the oxygen partial pressure is less than 1 torr but greater than 0 torr, or both the water vapor partial pressure and the oxygen partial pressure are respectively less than 1 torr but greater than 0 torr.

The present invention makes use of at least one robot to provide a more effective way of making OLED displays. An advantage of the method described in this invention is that it is useful in producing OLED devices without introducing moisture, oxygen, or other atmospheric components.

A further advantage is that this method can be fully automated including donor and substrate media handling. The present invention is particularly suitable for forming organic layers over a large area having a number of OLED display devices, which are in the process of being formed, thereby increasing throughput.

A further advantage is that added techniques can be used for coating, including solvent-based coating such as spin coating, curtain coating, spray coating, Gravure-wheel coating, and others.

### BRIEF DESCRIPTION OF THE DRAWINGS

FIG. 1 is a cross-sectional representation of a first embodiment of an apparatus including a first, second, and third stations to effect this invention;

FIG. 2 illustrates a manufacturing system including a series of stations in accordance with the present invention;

FIG. 3 illustrates an alternate embodiment of a manufacturing system including a series of stations in accordance with the present invention;

FIG. 4 illustrates an alternate embodiment of a manufacturing system including a series of stations in accordance with the present invention;

FIG. 5 illustrates an alternate embodiment of a manufacturing system including a series of stations in accordance with the present invention;

FIG. 6 illustrates an alternate embodiment of a manufacturing system including a series of stations in accordance with the present invention;

FIG. 7 an alternate embodiment of a manufacturing system including a series of stations in accordance with the present invention;

FIG. 8 is a block diagram showing the steps in one embodiment of the present invention;

FIG. 9 is a block diagram showing the steps in another embodiment of the present invention.

Since device feature dimensions such as layer thicknesses are frequently in sub-micrometer ranges, the drawings are scaled for ease of visualization rather than dimensional accuracy.

### DETAILED DESCRIPTION OF THE INVENTION

The term “OLED device” refers to a device including organic light-emitting diodes, sometimes called an electroluminescent device, and an EL device, as described by e.g. Tang in commonly assigned U.S. Pat. No. 5,937,272 and by Littman and Tang in commonly assigned U.S. Pat. No. 5,688,551. The term “display” or “display panel” is employed to designate a screen capable of electronically displaying video images or text. The term “pixel” is employed in its art-recognized usage to designate an area of a display panel that can be stimulated to emit light independently of other areas. The term “multicolor” is employed to describe a display panel that is capable of emitting light of a different hue in different areas. In particular, it is employed to describe a display panel that is capable of displaying images of different colors. These areas are not necessarily contiguous. The term “full color” is employed to describe multicolor display panels that are capable of emitting in the red, green, and blue regions of the visible spectrum and displaying images in any combination of hues. The red, green, and blue colors constitute the three primary color from which all other colors can be generated by appropriately mixing these three primaries. The term “hue” refers to the intensity profile of light emission within the visible spectrum, with different hues exhibiting visually discernible differences in color. The pixel or subpixel is generally used to designate the smallest addressable unit in a display panel. For a monochrome display, there is no distinction between pixel or subpixel. The term “subpixel” is used in multicolor display panels and is employed to designate any portion of a pixel which can be independently addressable to emit a specific color. For example, a blue subpixel is that portion of a pixel which can be addressed to emit blue light. In a full-color display, a pixel generally includes three primary-color subpixels, namely blue, green, and red. The term “pitch” is used to designate the distance separating two pixels or subpixels in a display panel. Thus, a subpixel pitch means the separation between two subpixels. The term “vacuum” is used herein to designate a pressure of 1 torr or less.

The present invention combines a radiation thermal transfer deposition subsystem(s) with conventional deposition subsystems to form an automated and scalable manufacturing system that provides a controlled environment throughout the entire manufacturing process. Such mixed-mode deposition under controlled environment is particularly well suited to the manufacture of OLED display devices.

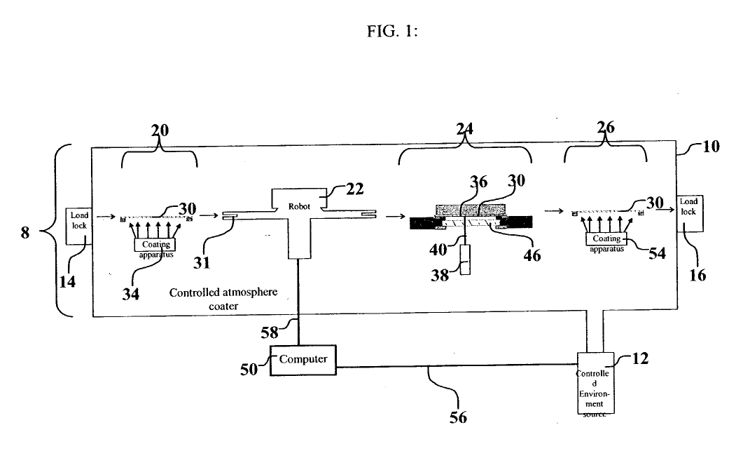

Turning now to FIG. 1, we see a cross-sectional representation of one embodiment of this invention in which an OLED substrate 30 is coated in three stations in the same controlled atmosphere coater 8. Controlled atmosphere coater 8 is an enclosed apparatus described herein that permits an in-situ method for fabricating an OLED device under controlled-environment conditions and includes unitary housing 10 which encompasses a first, second, and third stations and a robot. By controlled environment, we mean that the water vapor partial pressure is preferably 1 torr or less, or the oxygen partial pressure is preferably 1 torr or less, or both. This can be accomplished by maintaining a vacuum inside the controlled atmosphere coater 8. This can also be accomplished by maintaining a water vapor level of preferably 1000 ppm or less, or an oxygen level of preferably 1000 ppm or less, or both, at a total pressure greater than 1 torr inside controlled atmosphere coater 8. While controlled atmosphere coater 8 is shown as a single chamber, it can also include two or more chambers in which at least one chamber is maintained under a vacuum, and at least one chamber is maintained under a higher-pressure controlled environment as described above. Such an apparatus has been described previously by Boroson et al in above-cited commonly-assigned U.S. patent application Ser. No. 10/141,587. While it is impossible to reduce the quantities of water vapor and/or oxygen completely to zero, controlled environment conditions can reduce the quantities of these components to very low or imperceptible levels, such as 0.001 ppm. Controlling the environment can be achieved by various well-known methods, e.g. oxygen or water-vapor scrubbers, or the use of purified gasses. Controlled atmosphere coater 8 can include one chamber, or any number of chambers that can be connected by load locks or similarly-acting apparatus such as tunnels or buffer chambers, whereby donor elements and receiver elements can be transported without exposure to moisture and/or oxygen. The conditions are maintained in controlled atmosphere coater 8 by a means for controlling the atmosphere, e.g. controlled-environment source 12. Controlled atmosphere coater 8 can include load lock 14, which is used to load substrates 30, and load lock 16, which is used to unload completed OLED devices. Several embodiments of controlled atmosphere coater 8 have been more fully described by Boroson et al in above-cited commonly-assigned U.S. patent application Ser. No. 10/141,587.

The interior of this embodiment of controlled atmosphere coater 8 can include first station 20, robot 22, second station 24, and third station 26. It will be understood in this and subsequent systems that “first station”, “second station”, etc. are terms of convenience and do not necessarily imply a specific order of operation. In this embodiment, first, second, and third stations 20, 24, and 26 are sequentially positioned in line, so that the substrate 30 can be sequentially moved in line through the different stations. First station 20 is a means for coating one or more organic layers over the substrate 30 e.g. a structure for applying a hole-transporting material over the substrate 30 by e.g. vapor deposition or other substantially uniform means. Substrate 30 can be an organic solid, an inorganic solid, or a combination of organic and inorganic solids that provides a surface for receiving the emissive organic material from a donor. Substrate 30 can be rigid or flexible and can be processed as separate individual pieces, such as sheets or wafers, or as a continuous roll. Typical substrate element materials include glass, plastic, metal, ceramic, semiconductor, metal oxide, semiconductor oxide, semiconductor nitride, or combinations thereof. Substrate 30 can be a homogeneous mixture of materials, a composite of materials, or multiple layers of materials. Substrate 30 can be an OLED substrate, that is a substrate commonly used for preparing OLED devices, e.g. active-matrix low-temperature polysilicon TFT substrate. The substrate 30 can either be light transmissive or opaque, depending on the intended direction of light emission. The light transmissive property is desirable for viewing the EL emission through substrate 30. Transparent glass or plastic are commonly employed in such cases. For applications where the EL emission is viewed through the top electrode, the transmissive characteristic of substrate 30 is immaterial, and therefore can be light transmissive, light absorbing or light reflective. Substrate elements for use in this case include, but are not limited to, glass, plastic, semiconductor materials, ceramics, and circuit board materials.

Substrate 30 commonly includes a first electrode. The first electrode is most commonly an anode, although examples of cathodes on an OLED substrate are known in the art. The conductive anode layer is formed over the substrate and, when EL emission is viewed through the anode, should be transparent or substantially transparent to the emission of interest. Common transparent anode materials used in this invention are indium-tin oxide and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as an anode material. For applications where EL emission is viewed through the top electrode, the transmissive characteristics of the anode material are immaterial and any conductive material can be used, transparent, opaque or reflective. Examples of conductors for this application include, but are not limited to, gold, iridium, molybdenum, palladium, and platinum. Typical anode materials, transmissive or otherwise, have a work function of 4.1 eV or greater. Desired anode materials can be deposited by any suitable means such as evaporation, sputtering, chemical vapor deposition, or electrochemical means. Anode materials can be patterned using well-known photolithographic processes.

Coating means or coating apparatus 34 can represent e.g. a heated boat, a point vapor source, etc. It will be understood that other coating methods are possible, e.g. solvent coating, and that the relative positions of substrate 30 above or below coating apparatus 34 will depend on the type of coating. First station 20 can coat one or more organic layers on substrate 30. For example, the use of two or more coating apparatus 34, movable in relation to substrate 30, will allow multiple organic layers to be coated.

First station 20 can coat one or more organic layer(s), e.g. a hole-injecting layer or a hole-transporting layer. While not always necessary, it is often useful that a hole-injecting layer be provided in an organic light-emitting display. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in commonly-assigned U.S. Pat. No. 4,720,432, and plasma-deposited fluorocarbon polymers as described in commonly-assigned U.S. Pat. No. 6,208,075. Alternative hole-injecting materials reportedly useful in organic EL devices are described in EP 0 891 121 A1 and EP 1,029,909 A1.

Hole-transporting materials useful as coated material are well known to include compounds such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al commonly-assigned U.S. Pat. Nos. 3,567,450 and 3,658,520.

A more preferred class of aromatic tertiary amines are those which include at least two aromatic tertiary amine moieties as described in commonly-assigned U.S. Pat. Nos. 4,720,432 and 5,061,569. Such compounds include those represented by structural formula (A).

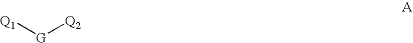

wherein Q₁ and Q₂ are independently selected aromatic tertiary amine moieties and G is a linking group such as an arylene, cycloalkylene, or alkylene group of a carbon to carbon bond. In one embodiment, at least one of Q₁, or Q₂ contains a polycyclic fused ring structure, e.g., a naphthalene. When G is an aryl group, it is conveniently a phenylene, biphenylene, or naphthalene moiety.

A useful class of triarylamines satisfying structural formula (A) and containing two triarylamine moieties is represented by structural formula (B):

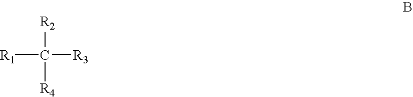

where R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural formula (C):

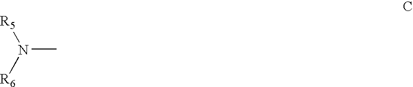

wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by formula (C), linked through an arylene group. Useful tetraaryldiamines include those represented by formula (D).

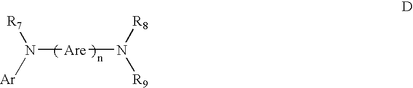

wherein each Are is an independently selected arylene group, such as a phenylene or anthracene moiety,

n is an integer of from 1 to 4, and

Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural formulae (A), (B), (C), (D), can each in turn be substituted. Typical substituents include alkyl groups, alkoxy groups, aryl groups, aryloxy groups, and halogen such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene moieties are usually phenyl and phenylene moieties.

The hole-transporting layer can be formed of a single or a mixture of aromatic tertiary amine compounds. Specifically, one can employ a triarylamine, such as a triarylamine satisfying the formula (B), in combination with a tetraaryldiamine, such as indicated by formula (D). When a triarylamine is employed in combination with a tetraaryldiamine, the latter is positioned as a layer interposed between the triarylamine and the electron injecting and transporting layer. Illustrative of useful aromatic tertiary amines are the following:

1, 1-Bis(4-di-p-tolylaminophenyl)cyclohexane

1, 1-Bis(4-di-p-tolylaminophenyl)-4-phenylcyclohexane

4,4′-Bis(diphenylamino)quadriphenyl

Bis(4-dimethylamino-2-methylphenyl)-phenylmethane

N,N,N-Tri(p-tolyl)amine

4-(di-p-tolylamino)-4′-[4(di-p-tolylamino)-styryl]stilbene

N,N,N′,N′-Tetra-p-tolyl-4-4′-diaminobiphenyl

N,N,N′,N′-Tetraphenyl-4,4′-diaminobiphenyl

N-Phenylcarbazole

Poly(N-vinylcarbazole), and

N,N′-di-1-naphthalenyl-N,N′-diphenyl-4,4′-diaminobiphenyl.

4,4′-Bis[N-(1-naphthyl)-N-phenylamino]biphenyl

4,4″-Bis[N-(1-naphthyl)-N-phenylamino]p-terphenyl

4,4′-Bis[N-(2-naphthyl)-N-phenylamino]biphenyl

4,4′-Bis[N-(3-acenaphthenyl)-N-phenylamino]biphenyl

1,5-Bis[N-(1-naphthyl)-N-phenylamino]naphthalene

4,4′-Bis[N-(9-anthryl)-N-phenylamino]biphenyl

4,4″-Bis[N-(1-anthryl)-N-phenylamino]-p-terphenyl

4,4′-Bis[N-(2-phenanthryl)-N-phenylamino]biphenyl

4,4′-Bis[N-(8-fluoranthenyl)-N-phenylamino]biphenyl

4,4′-Bis[N-(2-pyrenyl)-N-phenylamino]biphenyl

4,4′-Bis[N-(2-naphthacenyl)-N-phenylamino]biphenyl

4,4′-Bis[N-(2-perylenyl)-N-phenylamino]biphenyl

4,4′-Bis[N-(1-coronenyl)-N-phenylamino]biphenyl

2,6-Bis(di-p-tolylamino)naphthalene

2,6-Bis[di-(1-naphthyl)amino]naphthalene

2,6-Bis[N-(1-naphthyl)-N-(2-naphthyl)amino]naphthalene

N,N,N′,N′-Tetra(2-naphthyl)-4,4″-diamino-p-terphenyl

4,4′-Bis {N-phenyl-N-[4-(1-naphthyl)-phenyl]amino}biphenyl

4,4′-Bis[N-phenyl-N-(2-pyrenyl)amino]biphenyl

2,6-Bis[N,N-di(2-naphthyl)amine]fluorene

1,5-Bis[N-(1-naphthyl)-N-phenylamino]naphthalene

Another class of useful hole-transport materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Controlled atmosphere coater 8 also includes the robot 22. Robot 22 is an actuable robot control means for grasping and removing substrate 30 from first station 20 after substrate 30 has been coated, and positioning coated substrate 30 into second station 24 so that it is in a material transferring relationship with donor element 36. For the purposes of this discussion, a robot shall include the apparatus necessary to move a web in the case where substrate 30 is in the form of a continuous web or roll. Robot 22 can include a grasping means 31 by which it can grasp and remove substrate 30 from first station 20 and position the coated substrate 30 in second station 24.

Second station 24 is a station that can hold substrate 30 in a material transferring relationship with donor element 36, which includes emissive organic material. Second station 24 can be e.g. an apparatus such as that described by Phillips et al in above cited commonly-assigned U.S. patent application Ser. No. 10/021,410. Second station 24 is shown for convenience in the closed configuration, but it also has an open configuration in which the donor element and substrate loading and unloading occurs. By material transferring relationship we mean the coated side of donor element 36 is positioned in close contact with the receiving surface of substrate 30 and held in place by a means such as fluid pressure in a pressure chamber, as described by Phillips, et al. Second station 24 is constructed so as to facilitate forming an emissive layer on substrate 30 through the selective transfer of organic material from donor element 36 to substrate 30 by applying radiation from an actuable radiation means, e.g. a laser beam 40 from a laser 38, through transparent portion 46. Radiation transfer is herein defined as any mechanism such as sublimation, ablation, vaporization or other process whereby material can be transferred upon initiation by radiation. The irradiation of donor element 36 in a predetermined pattern selectively transfers one or more layers of coated material from donor element 36 to substrate 30 so that material will coat selected portions of substrate 30, as described by Phillips et al.

The emissive layer includes one or more emissive organic materials. Emissive organic materials useful as coated material are well known. As more fully described in commonly-assigned U.S. Pat. Nos. 4,769,292 and 5,935,721, the emissive layer (LEL) of the organic EL element include a luminescent or fluorescent material where electroluminescence is produced as a result of electron-hole pair recombination in this region. The emissive layer can be comprised of a single material, but more commonly consists of a host material doped with a guest compound or compounds where light emission comes primarily from the dopant and can be of any color. The host materials in the emissive layer can be an electron-transporting material, as defined below, a hole-transporting material, as defined above, or another material that supports hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material.

An important relationship for choosing a dye as a dopant is a comparison of the bandgap potential which is defined as the energy difference between the highest occupied molecular orbital and the lowest unoccupied molecular orbital of the molecule. For efficient energy transfer from the host to the dopant molecule, a necessary condition is that the band gap of the dopant is smaller than that of the host material.

Host and emitting molecules known to be of use include, but are not limited to, those disclosed in U.S. Pat. Nos. 4,768,292; 5,141,671; 5,150,006; 5,151,629; 5,294,870; 5,405,709; 5,484,922; 5,593,788; 5,645,948; 5,683,823; 5,755,999; 5,928,802; 5,935,720; 5,935,721, and 6,020,078.

Metal complexes of 8-hydroxyquinoline and similar derivatives (Formula E) constitute one class of useful host compounds capable of supporting electroluminescence, and are particularly suitable for light emission of wavelengths longer than 500 nm, e.g., green, yellow, orange, and red.

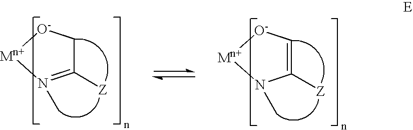

wherein

M represents a metal;

n is an integer of from 1 to 3; and

Z independently in each occurrence represents the atoms completing a nucleus having at least two fused aromatic rings.

From the foregoing it is apparent that the metal can be monovalent, divalent, or trivalent metal. The metal can, for example, be an alkali metal, such as lithium, sodium, or potassium; an alkaline earth metal, such as magnesium or calcium; or an earth metal, such as boron or aluminum. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:

CO-1: Aluminum trisoxine [alias, tris(8-quinolinolato)aluminum(III)]

CO-2: Magnesium bisoxine [alias, bis(8quinolinolato)magnesium(II)]

CO-3: Bis[benzo{f}-8-quinolinolato]zinc (II)

CO-4: Bis(2-methyl-8-quinolinolato)aluminum(III)-μ-oxo-bis(2-methyl-8-quinolinolato) aluminum(III)

CO-5: Indium trisoxine [alias, tris(8-quinolinolato)indium]

CO-6: Aluminum tris(5-methyloxine) [alias, tris(5-methyl-8-quinolinolato)aluminum(III)]

CO-7: Lithium oxine [alias, (8-quinolinolato)lithium(I)]

Derivatives of 9,10-di-(2-naphthyl)anthracene (Formula F) constitute one class of useful hosts capable of supporting electroluminescence, and are particularly suitable for light emission of wavelengths longer than 400 nm, e.g., blue, green, yellow, orange or red.

| | |
|---|---|
| F | 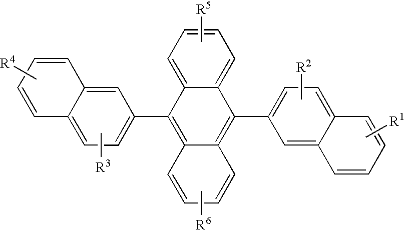 |

wherein: R¹, R², R³, and R⁴ represent one or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl; pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine, chlorine, bromine or cyano.

Benzazole derivatives (Formula G) constitute another class of useful hosts capable of supporting electroluminescence, and are particularly suitable for light emission of wavelengths longer than 400 nm, e.g., blue, green, yellow, orange or red.

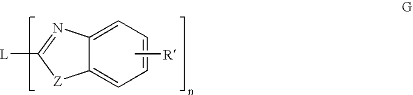

Where:

n is an integer of 3 to 8;

Z is O, NR or S; and

R′ is hydrogen; alkyl of from 1 to 24 carbon atoms, for example, propyl, t-butyl, heptyl, and the like; aryl or heteroatom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring;

L is a linkage unit consisting of alkyl, aryl, substituted alkyl, or substituted aryl, which conjugately or unconjugately connects the multiple benzazoles together.

An example of a useful benzazole is 2,2′,2″-(1,3,5-phenylene)tris[1-phenyl-1H-benzimidazole].

Desirable fluorescent dopants include derivatives of anthracene, tetracene, xanthene, perylene, rubrene, coumarin, rhodamine, quinacridone, dicyanomethylenepyran compounds, thiopyran compounds, polymethine compounds, pyrilium and thiapyrilium compounds, and carbostyryl compounds. Illustrative examples of useful dopants include, but are not limited to, the following:

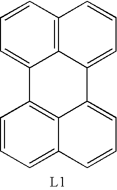

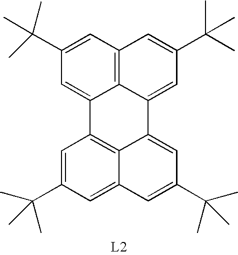

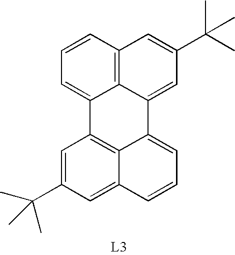

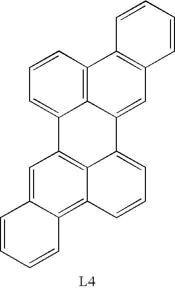

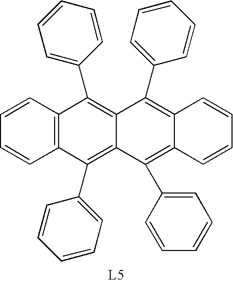

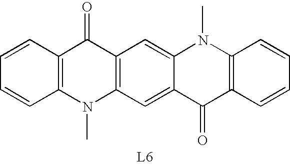

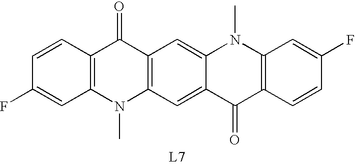

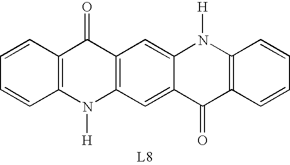

| | | |
|---|---|---|
| X | R1 | R2 |

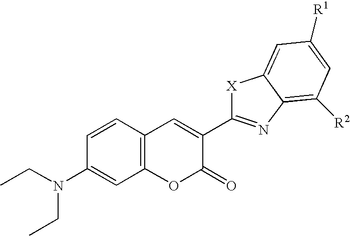

| | | | |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

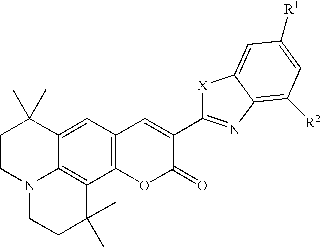

| | | | |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

R

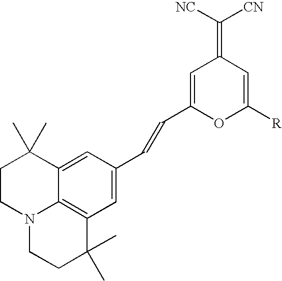

| | |
|---|---|
| L37 | phenyl |
| L38 | methyl |
| L39 | t-butyl |
| L40 | mesityl |

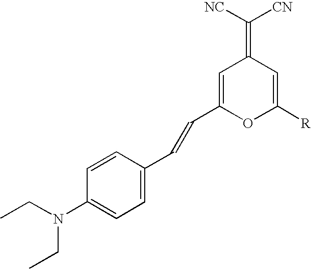

| | |
|---|---|
| L41 | phenyl |
| L42 | methyl |
| L43 | t-butyl |
| L44 | mesityl |

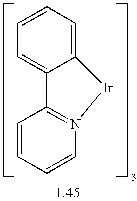

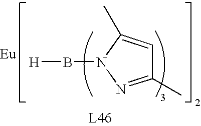

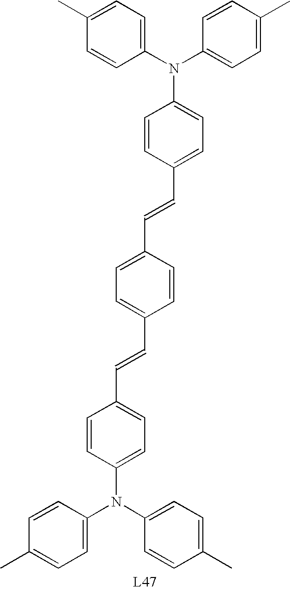

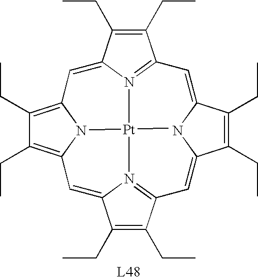

Other emissive organic materials can be polymeric substances, e.g. polyphenylenevinylene derivatives, dialkoxy-polyphenylenevinylenes, poly-para-phenylene derivatives, and polyfluorene derivatives, as taught by Wolk et al in U.S. Pat. No. 6,194,119 B1 and references therein.

Donor element 36 is an element coated with one or more coated organic layers that can produce part or all of an OLED device and that can subsequently be transferred in whole or in part such as by thermal transfer. The donor element 36 includes a donor support element. The donor support element has been described by Tang et al in commonly assigned U.S. Pat. No. 5,904,961 and which can be made of any of several materials or combinations of materials which meet at least the following requirements: the donor support element must be sufficiently flexible and possess adequate tensile strength to tolerate coating steps and roll-to-roll or stacked-sheet transport of the support in the practice of the invention. The donor support element must be capable of maintaining the structural integrity during the radiation-to-heat-induced transfer step while pressurized on one side, and during any preheating steps contemplated to remove volatile constituents such as water vapor. Additionally, the donor support element must be capable of receiving on one surface a relatively thin coating of material, and of retaining this coating without degradation during anticipated storage periods of the coated support. Support materials meeting these requirements include, for example, metal foils, plastic foils, and fiber-reinforced plastic foils. While selection of suitable support materials can rely on known engineering approaches, it will be appreciated that certain aspects of a selected support material merit further consideration when configured as a donor support element useful in the practice of the invention. For example, a donor support element can require a multi-step cleaning and surface preparation process prior to coating with material. If the support material is a radiation-transmissive material, the incorporation into a donor support element or onto a surface thereof, of a radiation-absorptive material can be advantageous to more effectively heat the donor support element and to provide a correspondingly enhanced transfer of material from donor element 36 to substrate 30, when using a flash of radiation from a suitable radiation source such as laser light from a suitable laser. The radiation-absorptive material can include a dye such as the dyes specified in commonly-assigned U.S. Pat. No. 5,578,416, a pigment such as carbon, or a metal such as nickel, chromium, titanium etc. Donor element 36 further includes light-emitting material as described above coated on the donor element. Donor element 36 can be introduced to unitary housing 10 by means of load lock 14 or load lock 16 and transferred by mechanical means to second station 24. This can occur before, after, or during the introduction of substrate 30.

Controlled atmosphere coater 8 also includes third station 26, which is a means for forming a second electrode over the first and second organic layers of emissive coated substrate 30 coated in first and second stations 20 and 24. Coating apparatus 54 can represent e.g. one or more heated boats for vaporizing electrode materials. The second electrode is most commonly a cathode. When light emission is through the anode, the cathode material can include nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprised of a thin layer of a low work function metal or metal salt capped with a thicker layer of conductive metal. One such cathode is comprised of a thin layer of LiF followed by a thicker layer of Al as described in commonly-assigned U.S. Pat. No. 5,677,572. Other useful cathode materials include, but are not limited to, those disclosed in commonly-assigned U.S. Pat. Nos. 5,059,861; 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in commonly-assigned U.S. Pat. No. 5,776,623. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

These operations can be simultaneous at the various stations. For example, the substrate 30 can be used in a radiation-induced transfer at second station 24, while a previously-transferred substrate 30 is being coated at third station 26 and an uncoated substrate 30 is being coated at first station 20.

A process control means, e.g. computer 50 can be arranged to control controlled-environment source 12 via data input/output 56. Robot 22 can be controlled by computer 50 via data input/output 58. Computer 50 can also be a process control means for controlling in a time sequence the actuation of the first, second, and third coating means, that is first, second, and third stations 20, 24, and 26, respectively. Computer 50 also controls the actuable robot control means, that is robot 22, and the actuable radiation means, that is laser 38.

Although FIG. 1 shows a system including three stations, this invention is not limited to three stations. For example, a fourth station can be provided in the controlled environment of unitary housing 10 for pretreating substrate 30 before being coated in first station 20. In a pretreatment step, substrate 30 can be cleaned or otherwise prepared for subsequent processing steps.

In another embodiment, a fourth (or a fifth) station can be provided in the controlled environment of unitary housing 10 for encapsulating the OLED device after forming a second electrode in third station 26. Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in commonly-assigned U.S. Pat. No. 6,226,890. In addition, barrier layers such as SiOx, Teflon, and alternating inorganic/polymeric layers are known in the art for encapsulation.

In another embodiment, a fourth station can be provided in the controlled environment of controlled atmosphere coater 8 for coating additional organic layers on substrate 30 after forming an emissive layer in second station 24. Such additional layers can include electron-transporting layers and electron-injecting layers.

Preferred electron-transporting materials for use in organic EL devices of this invention are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural formula (E), previously described.

Other electron-transporting materials include various butadiene derivatives as disclosed in commonly-assigned U.S. Pat. No. 4,356,429 and various heterocyclic optical brighteners as described in commonly-assigned U.S. Pat. No. 4,539,507. Benzazoles satisfying structural formula (G) are also useful electron transporting materials.

Other electron-transporting materials can be polymeric substances, e.g. polyphenylenevinylene derivatives, poly-para-phenylene derivatives, polyfluorene derivatives, polythiophenes, polyacetylenes, and other conductive polymeric organic materials such as those listed in U.S. Pat. No. 6,221,553 B1 and references therein.

In some instances, a single layer can serve the function of supporting both light emission and electron transportation, and will therefore include emissive material and electron transporting material.

An electron-injecting layer can also be present between the cathode and the electron-transporting layer. Examples of electron-injecting materials include alkali halide salts, such as LiF mentioned above.

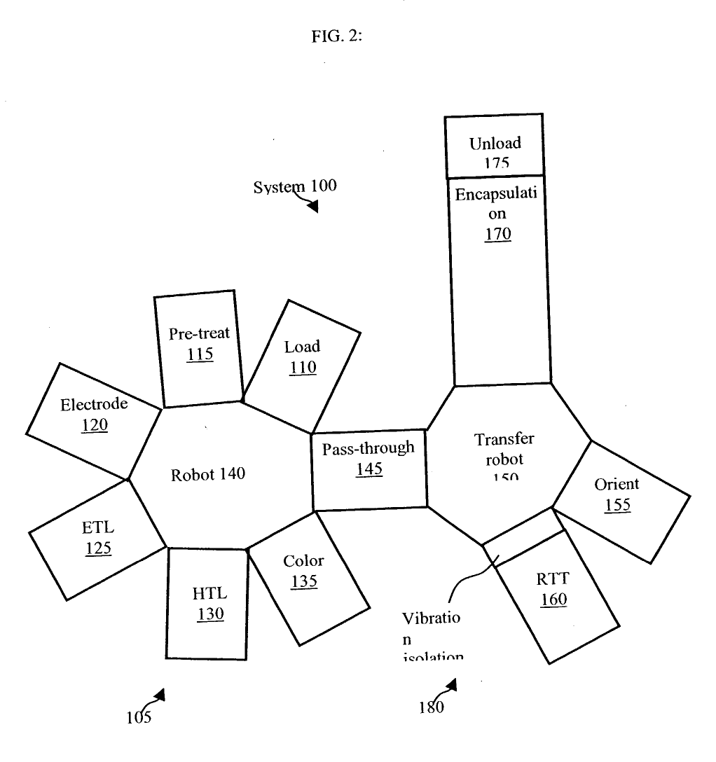

FIG. 2 illustrates in another embodiment of this invention a system 100 that combines radiation thermal transfer deposition with conventional deposition techniques such as linear source evaporation with or without shadow masks, as well as with other processes, under a controlled environment for making OLED display devices. System 100 includes a first cluster 105 and second cluster 180. First cluster 105 includes a first robot 140 and the surrounding stations. Second cluster 180 includes a second robot 150 and the surrounding stations. The nature of the surrounding stations will be further described. It will be evident to those skilled in the art that a variety of embodiments of system 100 are possible. For example, the entirety of system 100 can be enclosed in a controlled atmosphere coater as has already been described. In another embodiment, each station can be an individual controlled atmosphere coater, in which case system 100 includes first cluster 105 of controlled atmosphere coaters wherein first robot 140 selectively positions substrate 30 in the appropriate controlled atmosphere coater, and second cluster 180 of controlled atmosphere coaters wherein second robot 150 selectively positions substrate 30 in the appropriate controlled atmosphere coater. In another embodiment, first cluster 105 can be contained in a first vacuum chamber and second cluster 180 can be enclosed in a controlled environment coater or a second vacuum chamber.

System 100 includes a loading station 110 that includes an appropriate set of robotics for automatically sorting and inserting both donor elements 36 and substrates 30. Loading station 110 maintains a moisture-free environment and is further capable of being pumped down from atmospheric pressure to a vacuum condition that is appropriate for subsequent processing steps. In one embodiment, loading station 110 is a vacuum transport vessel that is capable of motion between the desired preprocessing stages, such as the one in which the donor elements 36 are precoated with the radiation-absorbing layer, to system 100, at which point loading station 110 can be docked to system 100.

The first robot 140 is disposed with respect to the elements of system 100 such that it facilitates the time-efficient transport of donor elements 36 and substrates 30 throughout the processing chambers while minimizing operator interface. In one embodiment, first robot 140 includes five central sets of robotics, each of which includes a docking station, which are implemented to facilitate the transport of donor elements 36 and substrates 30 throughout the chambers of system 100.

System 100 can include a first station 130, in which an organic layer such as a continuous hole-transporting layer can be coated atop the substrate 30 or the donor elements 36 using any of a variety of conventional deposition techniques, such as a linear evaporation source; a third station 125, in which an organic layer such as a continuous electron-transporting layer can be coated atop substrate 30 or donor elements 36 using any of a variety of conventional deposition techniques, such as a linear evaporation source; and a fourth station 120, in which electrodes such as transparent indium-tin-oxide (ITO) anodes and metallic cathodes can be separately disposed onto substrate 30, all of which are included in first cluster 105. In an alternate embodiment, first station 130 and third station 125 can be radiation thermal transfer stations in which the substrate 30 is patterned on a subpixel basis rather than continuously coated. System 100 can further include an appropriate pretreatment station 115, which can also be called a fifth station, in which the substrates 30 or the donor elements 36 can be cleaned or otherwise prepared for subsequent processing steps.

System 100 further includes an emissive layer coating station 135, in which the donor elements 36 are coated with red, green, or blue organic material that is to be subsequently transferred via radiation thermal transfer to the substrate 30 to form the emissive layer. System 100 further includes a pass-through 145 that is a transport chamber that maintains a controlled environment and the second robot 150 that is another set of robotics disposed with respect to the elements of system 100 such that it facilitates the time-efficient transport of donor elements 36 and substrates 30 throughout the processing chambers while minimizing operator interface. System 100 further includes an orientation station 155 that is a set of robotics designed to appropriately align substrates 36 with donor elements 36 in preparation for radiation thermal transfer. Orientation station 155 is sometimes necessary due to the fact that the deposition of layers prior to radiation thermal transfer occurs on the bottoms of the donor elements 36 and the substrates 30. The coated sides of donor elements 36 and substrates 30 must face one another for radiation thermal transfer to occur. In an alternate embodiment, either donor elements 36 or substrates 30 can receive coatings from the top or both donor sheets and substrates can receive coatings from the side, in which case orientation station 155 can be eliminated.

System 100 further includes a second station 160, in which emissive layer material is transferred from the donor elements 36 to the substrates 30, as well as a vibration isolation element 165, in which vibrations from the other elements of the system 100 are damped to minimize vibrations that can decrease radiation thermal transfer location accuracy. Vibration isolation can be desired if accurate placement of the radiation thermal transfer process is required, such as in full color pixilated devices. Vibration isolation can be achieved by any number of known active or passive vibration isolation methods. System 100 can further include an encapsulation station 170, in which the substrate 30, having all the desirable coatings, is encapsulated and environmentally sealed to form an OLED panel. Finally, system 100 includes an unloading station 175, in which the encapsulated OLED panel is withdrawn from manufacturing cell. In one embodiment, unloading station 175 is not under vacuum conditions, since the encapsulation layer protects the OLED panel.

In operation, system 100 maintains a controlled environment while combining all necessary processes for the mixed-mode manufacture of OLED display devices that includes radiation thermal transfer emissive layer deposition. Substrates 30 and donor elements 36 are inserted into system 100 at loading station 110. In one example, two substrates 30 and six donor elements 36 are loaded at a time into loading station 110 and into system 100. Loading station 110 sorts the substrates and donor sheets and, via first robot 140, transfers the substrates 30 and donor elements 36 to the appropriate next chamber. Donor elements 36, having a previously coated radiation-absorbing layer and optional anti-reflecting layer, are transferred to emissive layer coating station 135, in which a red, green, or blue emissive organic coating is deposited. Donor elements 36 are transferred through pass-through 145 via first robot 140, and into second station 160 via second robot 150 to await the radiation thermal transfer process.

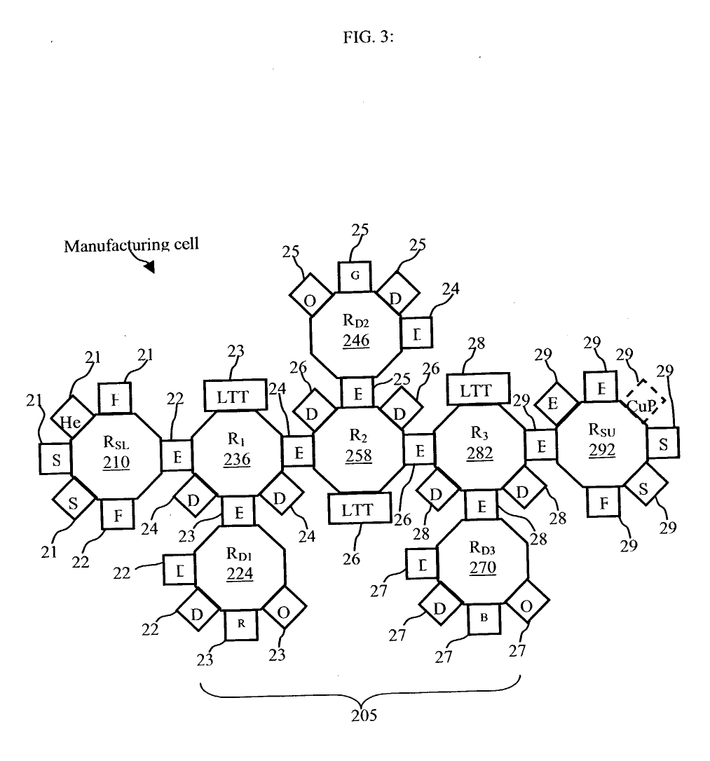

Substrates 30 are transferred via first robot 140 to pretreatment station 115, in which a pretreatment process occurs. First robot 140 then transfers substrates 30 to fourth station 120, in which an anode is applied. First robot 140 next transfers substrates 30 to first station 130, in which an organic hole-transporting layer is applied via a conventional deposition process such as linear evaporation. First robot 140 subsequently transfers substrates 30 to pass-through 145, at which point the substrates 30 are passed to second robot 150, which inserts the substrates 30 into second station 160. Prior to insertion into second station 160, either the substrates 30 or the donor elements 36 can be reoriented by orientation station 155, which orients substrates 30 and donor elements 36 such that their coated sides are facing one another in preparation for radiation thermal transfer. Once in second station 160, the donor elements 36 and substrates 30 are placed in a material transferring relationship, that is, in close proximity or in contact with one another, e.g., with a gap of between 0 and 10 microns therebetween. A radiation beam is swept and modulated across the donor element 36 in an appropriate sweep pattern, impinging through the support of the donor element 36, and is absorbed within the radiation-absorbing layer included atop the support. The conversion of the radiation beam's energy to heat within the radiation-absorbing layer transfers the organic coating atop the radiation-absorbing layer and thereby transfers the organic material in a desired subpixel pattern to substrate 30, producing a red, green, or blue subpixel array atop substrate 30. Two more radiation thermal transfer processes occur within second station 160 to the same substrate 30 using different color donor elements 36 to achieve the other two color subpixel arrays. Alternately, three separate radiation thermal transfer chambers can be included, as is described in reference to FIG. 3.

Upon completion of the deposition of the red, green, and blue emitting subpixel arrays that form the emissive layer atop substrate 30, substrate 30 is transferred via second robot 150 to pass-through 145, at which point substrates 30 are passed to first robot 140 and transferred to third station 125, in which a continuous electron-transporting layer is applied to substrates 30 via a conventional deposition process such as linear evaporation. First robot 140 next passes substrates 30 to fourth station 120, in which a metallic cathode is applied atop substrates 30. First robot 140 subsequently transfers the coated substrates 30 back to pass-through 145, at which point second robot 150 transfers coated substrates 30 to encapsulation station 170, in which substrates 30 receive a coating that environmentally seals them. Second robot 150 subsequently transfers substrates 30 to unloading station 175, at which point the finished OLED devices are removed system 100 to await post-processing steps, for example segmenting into individual displays.

Each of the chambers of system 100, while shown as if physically attached, can be connected by a vacuum transport chamber or translating vessel that maintains a controlled environment, defined as containing less than 1 torr partial pressure of water, less than 1 torr partial pressure of an oxidizing gas, or both. At no time during the manufacture of the OLED display device within system 100 is a non-controlled environment introduced to the donor elements 36 or the substrates 30. Any differences in vacuum pressures necessitated by consecutive processing chambers are achieved by an appropriate vacuum transport vessel that can be undocked from a chamber, pumped down to achieve the desired vacuum pressure, and docked to the next processing chamber.

FIG. 3 illustrates a system 200 for an increased throughput as opposed to the more typical system 100. System 200 includes a radiation thermal transfer station 205 including three separate radiation thermal transfer substations 238, 260, and 284 for separately positioning at least three different donor element 36 in material transferring relationship with substrates 30 to form different emissive layers on the substrate 30 by separately depositing the red, green, and blue subpixel arrays, respectively, atop substrates 30. System 200 includes a robot 210 that serves: a pair of substrate loading docks 212 and 214 that are vacuum transport vessels that dock to system 200; a deposition station 216, in which a continuous hole-transporting layer coating is deposited atop substrates 30 using any of a variety of conventional deposition techniques, such as a linear evaporation source; a heat treatment station 218; an orientation station 220; and a buffer 222. Robot 210 includes means for positioning a substrate 30 having an electrode in a first station, e.g. deposition station 216, which is a means for coating one or more organic layer(s) over substrate 30.

System 200 further includes a robot 224 for loading donor elements 36. Robot 224 serves: a pair of donor element loading docks 226 and 228 that are vacuum transport vessels that dock to system 200; an optional cleaning station 230 that pre-cleans the donor elements 36; an organic deposition station 232 that deposits red emissive organic material onto the donor elements 36 for subsequent radiation thermal transfer onto substrates 30; and buffer 234. System 200 further includes a robot 236 that serves: radiation thermal transfer substation 238, in which red emissive subpixels are deposited from the red emissive donor elements 36 to the substrates 30; a pair of donor unloading stations 240 and 242 at which the spent donor elements 36 are withdrawn from system 200; buffers 222; 234; and 244. Together, robot 210 and robot 236 comprise an actuable robot control means effective when actuated for grasping and removing substrate 30 from deposition station 216 and positioning coated substrate 30 into a second station, e.g. radiation thermal transfer substation 238, in material transferring relationship with a donor element 36 that includes emissive organic materials. Radiation thermal transfer substation 238 includes an actuable radiation means effective when actuated for applying radiation to donor element 36 to selectively transfer organic material from donor element 36 to substrate 30 to form an emissive layer on coated substrate 30.

System 200 further includes a robot 246 for loading donor elements 36. Robot 246 serves: a pair of donor element loading docks 248 and 250 that are vacuum transport vessels that dock to system 200; an optional cleaning station 252 that pre-cleans the donor elements 36; an organic deposition station 254 that deposits green emissive organic material onto the donor elements 36 for subsequent radiation thermal transfer onto substrates 30; and a buffer 256. System 200 further includes a robot 258 that serves: a radiation thermal transfer substation 260, in which green emissive subpixels are deposited from the green emissive donor elements 36 to substrates 30; a pair of donor unloading stations 262 and 264, at which the spent donor elements 36 are withdrawn from system 200; buffers 244; 256; and 268. Together, robot 236 and robot 258 comprise an actuable robot control means effective when actuated for grasping and removing substrate 30 from radiation thermal transfer station 238 and positioning coated substrate 30 into radiation thermal transfer substation 260, in material transferring relationship with a donor element 36 that includes emissive organic materials. Radiation thermal transfer substation 260 includes an actuable radiation means effective when actuated for applying radiation to donor element 36 to selectively transfer organic material from donor element 36 to substrate 30 to form an emissive layer on coated substrate 30.

System 200 further includes a robot 270 for loading donor elements 36. Robot 270 serves: a pair of donor element loading docks 272 and 274 that are vacuum transport vessels that dock to system 200; an optional cleaning station 276 that pre-cleans the donor elements 36; an organic deposition station 278 that deposits blue emissive organic material onto the donor elements 36 for subsequent radiation thermal transfer onto substrates 30; and a buffer 280. System 200 further includes a robot 282 that serves: radiation thermal transfer substation 284, in which blue emissive subpixels are deposited from the blue emissive donor elements 36 to substrates 30; a pair of donor unloading stations 286 and 288, at which the spent donor elements 36 are withdrawn from system 200; buffers 268; 280; and 290. Together, robot 258 and robot 282 comprise an actuable robot control means effective when actuated for grasping and removing substrate 30 from radiation thermal transfer station 260 and positioning coated substrate 30 into radiation thermal transfer substation 284, in material transferring relationship with a donor element 36 that includes emissive organic materials. Radiation thermal transfer substation 284 includes an actuable radiation means effective when actuated for applying radiation to donor element 36 to selectively transfer organic material from donor element 36 to substrate 30 to form an emissive layer on coated substrate 30.

Lastly, system 200 further includes a robot 292 for unloading substrate 30. Robot 292 serves: a pair of substrate unloading docks 298 and 299 that are vacuum transport vessels that dock to system 200; a deposition station 295, in which a continuous electron-transporting layer coating is deposited atop substrates 30 using any of a variety of conventional deposition techniques, such as a linear evaporation source; an optional deposition station 296 for depositing an electron-injecting layer such as copper phthalocyanine (CuPC); an electrode coating station 297; an orientation station 294; and buffer 290. Together, robot 282 and robot 292 comprise an actuable robot control means effective when actuated for grasping and removing emissive coated substrate 30 from radiation thermal transfer substation 284 and positioning emissive coated substrate 30 into a deposition station 295, which is a means for coating one or more second organic layer(s) over emissive layer coated substrate 30.

Buffers 222, 234, 244, 256, 268, 280, and 290 can be pass-throughs or vacuum transport vessels that maintain a controlled environment and provide storage space to accumulate substrates 30 or donor elements 36 in the event that a halt in production occurs downstream.

In system 200, the individual stations are comprised of clusters of controlled atmosphere coaters. For example, a first station for coating organic layers comprises a cluster of controlled atmosphere coaters surrounding robot 210. A second station for radiation thermal transfer comprises a cluster of controlled atmosphere coaters surrounding robots 236, 258, and 282. A third station for coating organic layers comprises a clusters of controlled atmosphere coaters surrounding robot 292.

In operation, substrates 30 are loaded into system 200 at substrate loading docks 212 and 214. Robot 210 transfers a substrate 30 to deposition station 216, in which a hole-transporting layer is deposited on the substrate. Robot 210 then transfers substrate 30 to heat treatment station 218, in which substrate 30 is heated. Robot 210 next transfers substrate 30 to orientation station 220, at which the substrate is oriented appropriately for subsequent radiation thermal transfer. Robot 210 then passes substrate 30 to buffer 222, in which the substrate is passed to robot 236. Concurrently, robot 224 passes a red-emissive coated donor element 36 through buffer 234 to robot 236. Robot 236 mates the donor element 36 to the substrate 30. Robot 236 transfers the donor element 36 and the substrate 36 to radiation thermal transfer substation 238, in which emissive material is transferred from the donor element 36 to the substrate 30 in the pattern of an array of red subpixels. The spent donor elements 36 are withdrawn from system 200 by donor unloading stations 240 and 242. Robot 236 next passes substrate 30 to buffer 244, in which it is passed to robot 258. Concurrently, robot 246 passes a green-emissive coated donor element 36 through buffer 256 to robot 258. Robot 258 mates the donor element 36 to substrate 30. Robot 258 transfers the donor element 36 and the substrate 30 to radiation thermal transfer substation 260, in which emissive material is transferred from the donor element 36 to the substrate 30 in the pattern of an array of green subpixels. The spent donor elements 36 are withdrawn from system 200 by donor unloading stations 262 and 264. Robot 258 next passes substrate 30 to buffer 268, in which it is passed to robot 282. Concurrently, robot 270 passes a blue-emissive coated donor element 36 through buffer 280 to robot 282. Robot 282 mates the donor element 36 to substrate 30. Robot 282 transfers the donor element 36 and substrate 30 to radiation thermal transfer substation 284, in which emissive material is transferred from the donor element 36 to the substrate 30 in the pattern of an array of blue subpixels. The spent donor elements 36 are withdrawn from system 200 by donor unloading stations 286 and 288. Robot 282 next passes substrate 30 to buffer 290, in which it is passed to robot 292. Robot 292 transfers substrate 30 to orientation station 294, at which point the substrate is oriented appropriately for deposition of an electron-transporting layer. Robot 292 next transfers substrate 30 to deposition station 295, in which an electron-transporting layer is deposited. Optionally, robot 292 next transfers substrate 30 to deposition station 296, in which an electron-injecting layer such as a copper phthalocyanine layer is deposited. Robot 292 next transfers substrate 30 to electrode coating station 297 in which an electrode layer is deposited. Robot 292 next transfers substrate 30 to substrate unloading dock 298 or 299, at which point substrate 30 is withdrawn from system 200 to undergo post-processing steps, such as deposition of an encapsulation layer.

Concurrently to the aforementioned processing of substrate 30, robot 224 continuously inserts donor elements 36 into system 200 from donor element loading docks 226 and 228. Robot 224 transfers a donor element 36 from donor element loading dock 226 or 228 to optional cleaning station 230, in which the donor element 36 is pre-cleaned. Robot 224 then transfers the donor element 36 to organic deposition station 232, in which red-emissive organic material is deposited atop the donor element 36, which is to be subsequently transferred via radiation thermal transfer to substrate 36 to form the array of red subpixels. Robot 224 next transfers donor element 36 to buffer 234, in which it is passed to robot 236. Similarly and concurrently, robot 246 continuously inserts donor elements 36 into system 200 from donor element loading docks 248 and 250. Robot 246 transfers a donor element 36 from donor element loading dock 248 or 250 to optional cleaning station 252, in which donor element 36 is pre-cleaned. Robot 246 then transfers the donor element 36 to organic deposition station 254, in which green-emissive organic material is deposited atop the donor element 36, which is to be subsequently transferred via radiation thermal transfer to substrate 30 to form the array of green subpixels. Robot 246 next transfers donor element 36 to buffer 256, in which it is passed to robot 258. Similarly and concurrently, robot 270 continuously inserts donor elements 36 into system 200 from donor element loading docks 272 and 274. Robot 270 transfers a donor element 36 from donor element loading dock 272 or 274 to optional cleaning station 276, in which the donor element 36 is pre-cleaned. Robot 270 then transfers the donor element 36 to organic deposition station 278, in which blue-emissive organic material is deposited atop the donor element 36, which is to be subsequently transferred via radiation thermal transfer to substrate 30 to form the array of blue subpixels. Robot 270 next transfers donor element 36 to buffer 280, in which it is passed to robot 282.

The inclusion of a pair of substrate loading docks 212 and 214 enables undisrupted manufacturing by allowing substrates 30 to be loaded from substrate loading dock 212 until empty, at which point substrates 30 are loaded from substrate loading dock 214 while substrate loading dock 212 is replenished. For similar throughput reasons, pairs of donor element loading docks 226 and 228, 248 and 250, and 272 and 274; pairs of donor unloading stations 240 and 242, 262 and 264, and 286 and 288; and a pair of substrate unloading docks 298 and 299 are included in system 200.

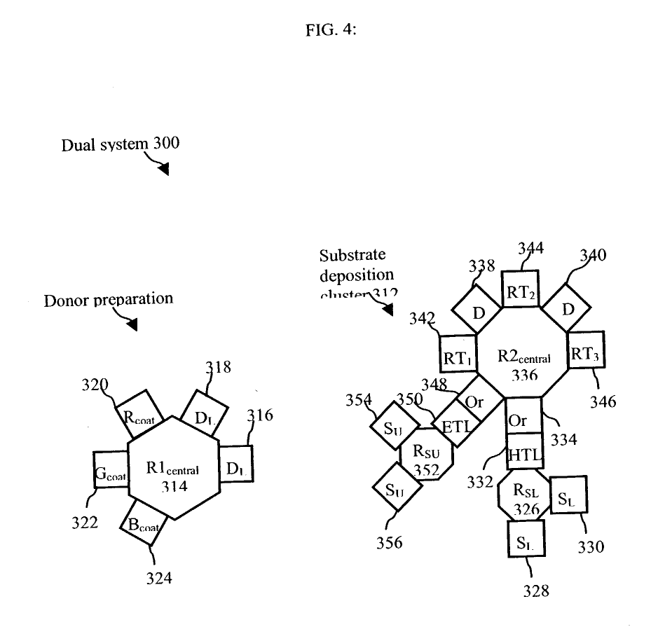

FIG. 4 illustrates a dual system 300 in which donor elements 36 and substrates 30 are treated separately. A substrate deposition cluster 312 includes three separate radiation thermal transfer stations 342, 344, and 346, each of which performs radiation thermal transfer of all three color subpixels to separate substrates 30 to provide a throughput commensurate with system 200. Substrate deposition cluster 312 further includes a robot 326 that serves: a pair of substrate loading docks 328 and 330 that are controlled-environment transport vessels that dock to substrate deposition cluster 312; an organic deposition station 332 in which a continuous hole-transporting layer coating is deposited atop substrates 30 using any of a variety of conventional deposition techniques, such as a linear evaporation source; and an orientation station 334. Substrate deposition cluster 312 further includes a central robot 336 that serves radiation thermal transfer stations 342, 344, and 346, as well as a pair of donor unloading stations 338 and 340, at which the spent donor elements 36 are withdrawn from substrate deposition cluster 312. Substrate deposition cluster 312 further includes a robot 352 that serves: a pair of substrate unloading docks 354 and 356 that are controlled-environment transport vessels that dock to substrate deposition cluster 312; an organic deposition station 350, in which a continuous electron-transporting layer coating is deposited atop substrates 30 using any of a variety of conventional deposition techniques, such as a linear evaporation source; and an orientation station 348.

In addition to substrate deposition cluster 312, dual system 300 further includes a donor preparation cluster 310 that prepares donor elements 36 for the subsequent radiation thermal transfer processes that occur in substrate deposition cluster 312. Donor preparation cluster 310 includes a central robot 314 that serves: a pair of donor element loading and unloading docks 316 and 318 that are controlled-environment transport vessels that dock to donor preparation cluster 310 and each of which has loading and unloading functionality; an organic deposition station 320 that deposits red-emissive organic material onto donor elements 36 for subsequent radiation thermal transfer onto substrates 30; an organic deposition station 322 that deposits green-emissive organic material onto a separate series of donor elements for subsequent radiation thermal transfer onto substrates 30; and an organic deposition station 324 that deposits blue-emissive organic material onto a separate series of donor elements 36 for subsequent radiation thermal transfer onto substrates 30.

Donor elements 36 that are prepared in donor preparation cluster 310 can be transferred from donor element loading docks 316 and 318 to substrate deposition cluster 312 at donor unloading stations 338 and 340 using a transport vessel that maintains a suitable controlled environment and is capable of docking to donor preparation cluster 310 and substrate deposition cluster 312.

The inclusion of the pair of substrate loading docks 328 and 330 enables undisrupted manufacturing by allowing substrates 30 to be loaded from substrate loading dock 328 until empty, at which point substrates 30 are loaded from substrate loading dock 330 while substrate loading dock 328 is replenished. For similar throughput reasons, the pair of donor element loading docks 316 and 318, the pair of donor unloading stations 338 and 340, and the pair of substrate unloading docks 354 and 356 are included in dual system 300.

In another embodiment, a plurality of donor preparation clusters 310 can prepare donor elements 36 for substrate deposition cluster 312.

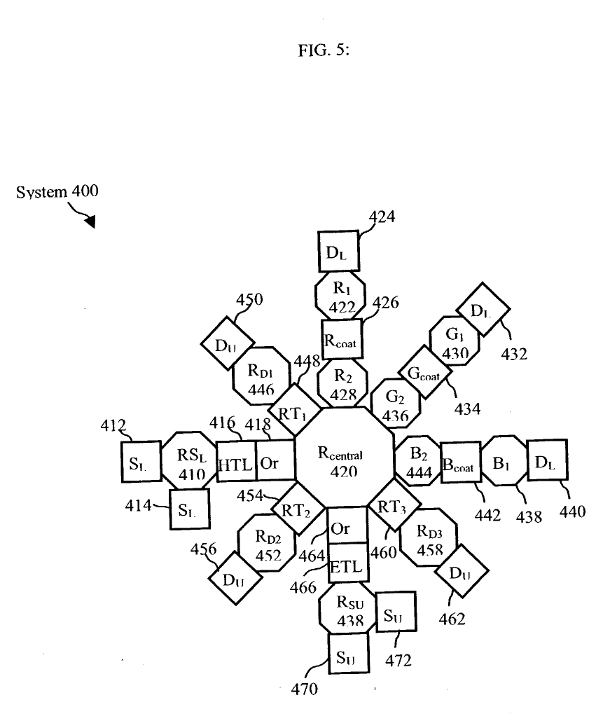

FIG. 5 illustrates a system 400 in which a central robot 420 is fed by a plurality of lines, three of which prepare the different color emissive donor elements 36; three of which include a radiation thermal transfer station 448, 454, and 460, each of which performs radiation thermal transfer of all three color subpixels to separate substrates 30; one of which prepares substrate 30 for radiation thermal transfer; and one of which processes substrates 30 subsequent to radiation thermal transfer. System 400 includes a robot 410 that serves: a pair of substrate loading docks 412 and 414 that are controlled environment transport vessels that dock to system 400; an organic deposition station 416 in which a continuous hole-transporting layer coating is deposited atop substrates 30 using any of a variety of conventional deposition techniques, such as a linear evaporation source; and an orientation station 418.

System 400 further includes a robot 422 that serves: a donor element loading dock (DL) 424 that is a controlled environment transport vessel that docks to system 400, and an organic deposition station 426 that deposits red-emissive organic material onto the donor elements 36 for subsequent radiation thermal transfer onto substrates 30. Robot 428 transfers red-emissive donor elements 36 from organic deposition station 426 to robot 420. System 400 further includes a robot 430 that serves: a donor element loading dock 432 that is a controlled environment transport vessel that docks to system 400, and an organic deposition station 434 that deposits green-emissive organic material onto the donor elements 36 for subsequent radiation thermal transfer onto substrates 30. A robot 436 transfers green-emissive donor sheets from organic deposition station 434 to robot 420. System 400 further includes a robot 438 that serves: a donor element loading dock 440 that is a controlled environment transport vessel that docks to system 400, and an organic deposition station 442 that deposits blue-emissive organic material onto the donor elements 36 for subsequent radiation thermal transfer onto substrates 30. Robot 444 transfers blue-emissive donor sheets from organic deposition station 442 to robot 420.

System 400 further includes a robot 446 that serves radiation thermal transfer station 448 and a donor unloading station 450, at which spent donor elements 36 are withdrawn from system 400; a robot 452 that serves radiation thermal transfer station 454 and a donor unloading station 456, at which the spent donor elements 36 are withdrawn from system 400; and a robot 458 that serves radiation thermal transfer station 460 and a donor unloading station 462, at which the spent donor elements 36 are withdrawn from system 400. System 400 further includes a robot 468 that serves: a pair of substrate unloading docks 470 and 472 that are controlled environment transport vessels that dock to system 400; an organic deposition station 466 in which a continuous electron-transporting layer coating is deposited atop substrates 30 using any of a variety of conventional deposition techniques, such as a linear evaporation source; and an orientation station 464.

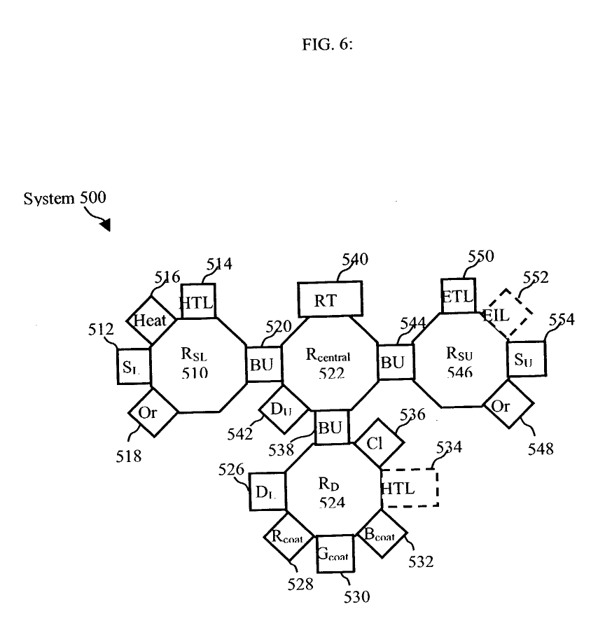

FIG. 6 illustrates a system 500 that is a mini-production facility in which a single radiation thermal transfer deposition station 540 is included to perform all three color subpixel depositions. System 500 includes a robot 510 that serves: a substrate loading dock 512 that is a controlled environment transport vessel that docks to system 500; an organic deposition station 514 in which a continuous hole-transporting layer coating is deposited atop substrates 30 using any of a variety of conventional deposition techniques, such as a linear evaporation source; a heat treatment station 516; an orientation station 518; and a buffer 520.

System 500 further includes robot 524 that serves: a donor element loading dock 526 that is a controlled environment transport vessel that docks to system 500; an optional cleaning station 536 that pre-cleans the donor elements 36; an organic deposition station 528 that deposits red-emissive organic material onto the donor elements 36 for subsequent radiation thermal transfer onto substrates 30; an organic deposition station 530 that deposits green-emissive organic material onto the donor elements 36 for subsequent radiation thermal transfer onto substrates 30; an organic deposition station 532 that deposits blue-emissive organic material onto the donor elements 36 for subsequent radiation thermal transfer onto substrates 30; an optional organic deposition station 534 for depositing hole-transporting material onto the donor elements 36 for subsequent radiation thermal transfer onto substrates 30; and a buffer 538.

System 500 further includes a robot 522 that serves: a radiation thermal transfer station 540, in which red-, green-, and blue-emissive organic material is deposited in separate steps from the red-, green-, and blue-emissive coated donor elements 36, respectively, to substrates 30; a donor unloading station 542 at which the spent donor elements 36 are withdrawn from system 500; buffers 520, 538, and 544. Lastly, system 500 includes a robot 546 that serves: a substrate unloading dock 554 that is a controlled environment transport vessel that docks to system 500; an organic deposition station 550 in which a continuous electron-transporting layer coating is deposited atop substrates 30 using any of a variety of conventional deposition techniques, such as a linear evaporation source; an optional organic deposition station 552 for depositing an electron-injecting layer such as copper phthalocyanine; an orientation station 548; and buffer 544.

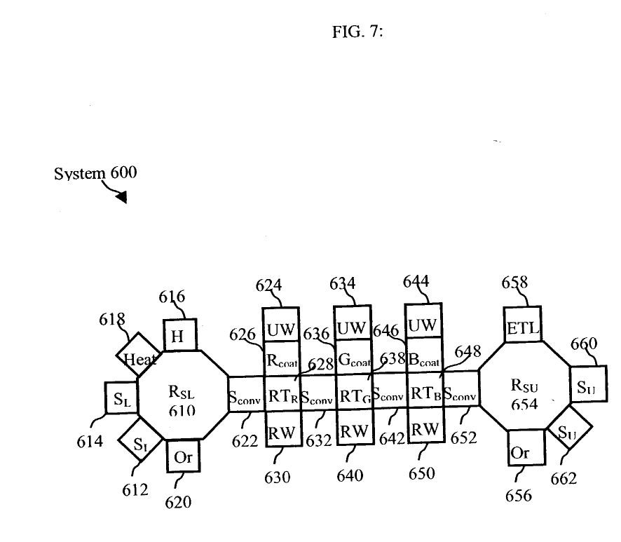

FIG. 7 illustrates a system 600 that uses a continuous roll of donor web rather than discrete framed donor elements 36. System 600 includes a structure or series of structures for separately positioning at least three different donor elements 36 in material transferring relationship with the substrate 30 to form different emissive layers on the substrate 30. System 600 includes a substrate loading robot 610 that serves: a pair of substrate loading docks 612 and 614 that are controlled environment transport vessels that dock to system 600; an organic deposition station 616 in which a continuous hole-transporting layer coating is deposited atop substrates 30 using any of a variety of conventional deposition techniques, such as a linear evaporation source; a heat treatment station 618; an orientation station 620; and a substrate conveying means 622 that in one example is a conveyor belt, by which the substrates 30 translate to a red radiation thermal transfer station 628.

System 600 further includes a donor web unwind chamber 624 in which a roll of uncoated donor web unwinds; an organic deposition station 626 through which the donor web translates and in which red-emissive organic material is deposited onto the donor web for subsequent radiation thermal transfer onto substrates 30; radiation thermal transfer station 628, through which the donor web translates and in which radiation thermal transfer occurs from the red-emissive coated donor web onto substrate 30; and a donor web rewind chamber 630 in which the spent donor web winds onto a take-up spool.

System 600 further includes a donor web unwind chamber 634 in which a roll of uncoated donor web unwinds; an organic deposition station 636 through which the donor web translates and in which green-emissive organic material is deposited onto the donor web for subsequent radiation thermal transfer onto substrates 30; a radiation thermal transfer station 638, through which the donor web translates and in which radiation thermal transfer occurs from the green-emissive coated donor web onto substrate 30; and a donor web rewind chamber 640 in which the spent donor web winds onto a take-up spool.

System 600 further includes a donor web unwind chamber 644 in which a roll of uncoated donor web unwinds; an organic deposition station 646 through which the donor web translates and in which blue-emissive organic material is deposited onto the donor web for subsequent radiation thermal transfer onto substrates 30; a radiation thermal transfer station 648, through which the donor web translates and in which radiation thermal transfer occurs from the blue-emissive coated donor web onto substrate 30; and a donor web rewind chamber 650 in which the spent donor web winds onto a take-up spool.

System 600 further includes a substrate unloading robot 654 that serves: a pair of substrate unloading docks 660 and 662 that are controlled environment transport vessels that dock to system 600; an organic deposition station 658 in which a continuous electron-transporting layer coating is deposited atop substrates 30 using any of a variety of conventional deposition techniques, such as a linear evaporation source; and an orientation station 656. System 600 further includes a substrate conveying means 632, by which the substrates 30 translate from radiation thermal transfer station 628 to radiation thermal transfer station 638; a substrate conveying means 642, by which the substrates 36 translate from radiation thermal transfer station 638 to radiation thermal transfer station 648; and a substrate conveying means 652, by which the substrates 30 translate from radiation thermal transfer station 648 to robot 654.

In an alternate embodiment of system 600, substrate 30 can also be supplied in the form of a flexible web. Such a use of a flexible substrate web has been described by Phillips et al in above cited commonly-assigned U.S. patent application Ser. No. 10/224,182.

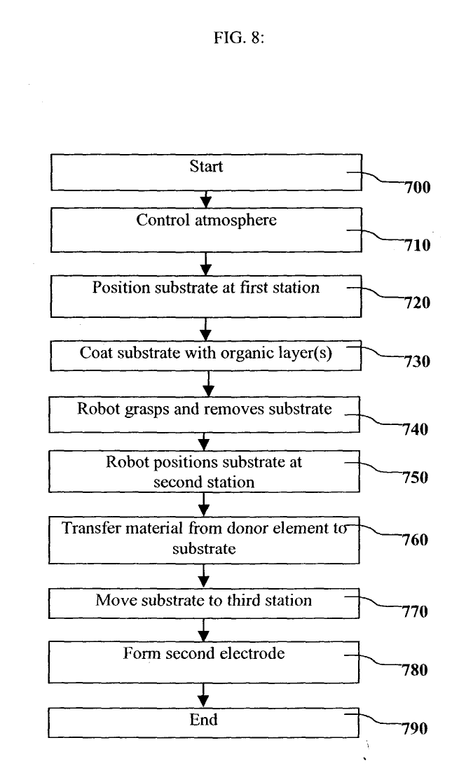

Turning now to FIG. 8, and referring also to FIG. 1, there is shown a block diagram comprising the steps in one embodiment of a method for forming an organic light-emitting device according to the present invention. At the start (Step 700) of the process, the atmosphere of controlled atmosphere coater 8 is controlled as has been described above, thereby controlling the atmosphere in the first, second, and third stations 20, 24, and 26, and in which robot 22 operates (Step 710). A substrate 30 having an electrode is positioned at first station 20 (Step 720). An organic layer, e.g. a hole-transporting layer is then coated over substrate 30 by coating apparatus 34 (Step 730). Then robot 22 grasps and removes substrate 30 from first station 20 (Step 740), and positions the coated substrate 30 at second station 24 (Step 750). Substrate 30 is positioned in a material transferring relationship with donor element 36 that includes emissive organic material. Second station 24 applies radiation, e.g. laser beam 40, to donor element 36 to selectively transfer organic material, e.g. emissive material from donor element 36 to substrate 30 by radiation thermal transfer to form an organic emissive layer on coated substrate 30 (Step 760). Then substrate 30 is moved to third station 26 by any of a variety of means, e.g. manually or by the same or another robot (Step 770). A second electrode is formed in third station 26 over the organic emissive layer(s) of emissive coated substrate 30 (Step 780), at which point the process ends (Step 790). As has been described above, various other steps are also possible, e.g. formation of a first electrode if one has not already been included on substrate 30, formation of an electron-transporting layer, etc.

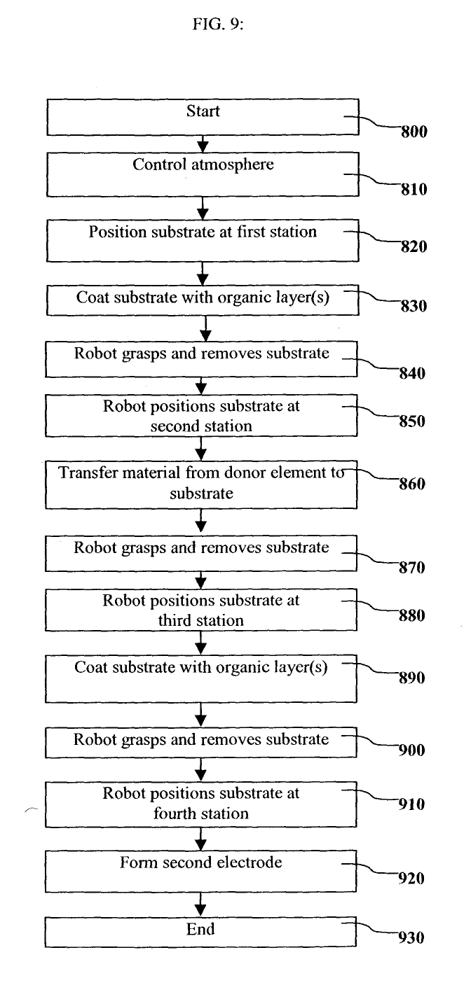

Turning now to FIG. 9, and referring also to FIG. 1 and FIG. 2, there is shown a block diagram comprising the steps in another embodiment of a method for forming an organic light-emitting device according to the present invention. At the start (Step 800) of the process, the atmosphere of system 100 is controlled as has been described above, thereby controlling the atmosphere in the first, second, third, and fourth stations 130, 160, 125, and 120, and in which robots 140 and 150 operate (Step 810). A substrate 30 having an electrode is positioned at first station 130 (Step 820). An organic layer, e.g. a hole-transporting layer is then coated over substrate 30 by coating apparatus 34 (Step 830). Then robot 140 grasps and removes substrate 30 from first station 130 (Step 840). Robot 140 transfers substrate 30 through pass-through 145 to robot 150. Robot 150 positions the coated substrate 30 at second station 160 (Step 850). Substrate 30 is positioned in a material transferring relationship with donor element 36 that includes emissive organic material. Second station 160 applies radiation, e.g. laser beam 40, to donor element 36 to selectively transfer organic material, e.g. emissive material from donor element 36 to substrate 30 by radiation thermal transfer to form an organic emissive layer on coated substrate 30 (Step 860). Then robot 150 grasps and removes emissive coated substrate 30 from second station 160 (Step 870). Robot 150 transfers emissive coated substrate 30 through pass-through 145 to robot 140. Robot 140 positions emissive coated substrate 30 in third station 125 (Step 880). At third station 125, one or more second organic layers, e.g. electron-transporting layer(s), are coated over the emissive layer coated substrate 30 (Step 890). Then robot 140 grasps and removes emissive coated substrate 30 from third station 125 (Step 900) and positions the emissive coated substrate 30 in fourth station 120 (Step 910). A second electrode is formed in fourth station 120 over the organic emissive layer(s) of emissive coated substrate 30 (Step 920), at which point the process ends (Step 930). As has been described above, various other steps are also possible, e.g. formation of a first electrode if one has not already been included on substrate 30, etc.

The invention has been described in detail with particular reference to certain preferred embodiments thereof, but it will be understood that variations and modifications can be effected within the spirit and scope of the invention.

### Parts List

8 controlled atmosphere coater

10 unitary housing

12 controlled environment source

14 load lock

16 load lock

20 first station

22 robot

24 second station

26 third station

30 substrate

31 grasping means

34 coating apparatus

36 donor element

38 laser

40 laser beam

46 transparent portion

50 computer

54 coating apparatus

56 data input/output

58 data input/output

100 system

105 first cluster

110 loading station

115 pretreatment station

120 fourth station

125 third station

130 first station

135 emissive layer coating station

140 first robot

145 pass-through

150 second robot

155 orientation station

160 second station

165 vibration isolation element

170 encapsulation station

175 unloading station

180 second cluster

200 system

205 radiation thermal transfer station

210 robot

212 substrate loading dock

214 substrate loading dock

216 deposition station

218 heat treatment station

220 orientation station

222 buffer

224 robot

226 donor element loading dock

228 donor element loading dock

230 cleaning station

232 organic deposition station

234 buffer

236 robot

238 radiation thermal transfer substation

240 donor unloading station

242 donor unloading station

244 buffer

246 robot

248 donor element loading dock

250 donor element loading dock

252 cleaning station

254 organic deposition station

256 buffer

258 robot

260 radiation thermal transfer substation

262 donor unloading station

264 donor unloading station

268 buffer

270 robot

272 donor element loading dock

274 donor element loading dock

276 cleaning station

278 organic deposition station

280 buffer

282 robot

284 radiation thermal transfer substation

286 donor unloading station

288 donor unloading station

290 buffer

292 robot

294 orientation station

295 deposition station

296 deposition station

297 electrode coating station

298 substrate unloading dock

299 substrate unloading dock

300 system

310 donor preparation cluster

312 substrate deposition cluster

314 robot

316 donor element loading dock

318 donor element loading dock

320 organic deposition station

322 organic deposition station

324 organic deposition station

326 robot

328 substrate loading dock

330 substrate loading dock

332 organic deposition station

334 orientation station

336 robot

338 donor unloading station

340 donor unloading station

342 radiation thermal transfer station

344 radiation thermal transfer station

346 radiation thermal transfer station

348 orientation station

350 organic deposition station

352 robot

354 substrate unloading dock

356 substrate unloading dock

400 system

410 robot

412 substrate loading dock

414 substrate loading dock

416 organic deposition station

418 orientation station

420 robot

422 robot

424 donor element loading dock

426 organic deposition station

428 robot

430 robot

432 donor element loading dock

434 organic deposition station

436 robot

438 robot

440 donor element loading dock

442 organic deposition station

444 robot

446 robot

448 radiation thermal transfer station

450 donor unloading station

452 robot

454 radiation thermal transfer station

456 donor unloading station

458 robot

460 radiation thermal transfer station

462 donor unloading station

464 orientation station

466 organic deposition station

468 robot

470 substrate unloading dock

472 substrate unloading dock

500 system

510 robot

512 substrate loading dock

514 organic deposition station

516 heat treatment station

518 orientation station

520 buffer

522 robot

524 robot

526 donor element loading dock

528 organic deposition station

530 organic deposition station

532 organic deposition station

534 organic deposition station

536 cleaning station

538 buffer

540 radiation thermal transfer station

542 donor unloading station

544 buffer

546 robot

548 orientation station

550 organic deposition station

552 organic deposition station

554 substrate unloading dock

600 system

610 robot

612 substrate loading dock

614 substrate loading dock

616 organic deposition station

618 heat treatment station

620 orientation station

622 substrate conveying means

624 donor web unwind chamber

626 organic deposition station

628 radiation thermal transfer station

630 donor web rewind chamber

632 substrate conveying means

634 donor web unwind chamber

636 organic deposition station

638 radiation thermal transfer station

640 donor web rewind chamber

642 substrate conveying means

644 donor web unwind chamber

646 organic deposition station

648 radiation thermal transfer station

650 donor web rewind chamber

652 substrate conveying means

654 robot

656 orientation station

658 organic deposition station

660 substrate unloading dock

662 substrate unloading dock

700 block

710 block

720 block

730 block

740 block

750 block

760 block

770 block

780 block

790 block

800 block

810 block

820 block

830 block

840 block

850 block

860 block

870 block

880 block

890 block

900 block

910 block

920 block

930 block

What is claimed is:

1. A method of making an OLED device comprising, in a controlled environment, the steps of:
a) positioning a substrate having an electrode in a first station and coating one or more first organic layer(s) over the substrate;
b) using a robot to grasp and remove the substrate from the first station and positioning the coated substrate into a second station, in material transferring relationship with a donor element that includes emissive organic material;
c) applying radiation to the donor element to selectively transfer organic material from the donor element to the substrate to form an emissive layer on the coated substrate;
d) forming a second electrode in a third station over the one or more second organic layers of the emissive coated substrate; and
e) controlling the atmosphere in the first, second, and third stations and in which the robot operates so that the water vapor partial pressure is less than 1 torr but greater than 0 torr, or the oxygen partial pressure is less than 1 torr but greater than 0 torr, or both the water vapor partial pressure and the oxygen partial pressure are respectively less than 1 torr but greater than 0 torr.

2. The method of claim 1 further including sequentially positioning the first, second, and third stations in line, and sequentially moving the substrate in line through the different stations.

3. The method of claim 1 further including providing a fourth station in the controlled environment for encapsulating the OLED device after step d).

4. The method of claim 1 further including providing a fourth station for pretreating the substrate prior to step a).

5. The method of claim 1 wherein the first station includes a first vacuum chamber and a structure for applying a hole-transporting material over the substrate.

6. The method of claim 1 wherein the first station includes a first cluster of controlled atmosphere coaters and the one or more robots selectively positions the substrate in the appropriate controlled atmosphere coater.

7. The method of claim 1 further including a unitary housing encompassing the first, second, and third stations and the robot, and having the controlled atmosphere.

8. A method of making an OLED device comprising, in a controlled environment, the steps of:
a) positioning a substrate having an electrode in a first station and coating one or more first organic layer(s) over the substrate;
b) using a robot to grasp and remove the substrate from the first station and positioning the coated substrate into a second station, in material transferring relationship with a donor element that includes emissive organic material;
c) applying radiation to the donor element to selectively transfer organic material from the donor element to the substrate to form an emissive layer on the coated substrate;
d) using the same or a different robot to grasp the substrate and remove the emissive coated substrate from the second station and positioning the emissive coated substrate in a third station, and coating one or more second organic layers over the emissive layer coated substrate;
e) using the same or a different robot to grasp the emissive coated substrate and remove such emissive coated substrate from the third station, and positioning the emissive coated substrate in a fourth station;
f) forming a second electrode in the fourth station over the one or more second organic layers of the emissive coated substrate; and
g) controlling the atmosphere in the first, second, third, and fourth stations and in which the robot(s) operate so that the water vapor partial pressure is less than 1 torr but greater than 0 torr, or the oxygen partial pressure is less than 1 torr but greater than 0 torr, or both the water vapor partial pressure and the oxygen partial pressure are respectively less than 1 torr but greater than 0 torr.

9. The method of claim 8 further including sequentially positioning the first, second, third, and fourth stations in line, and sequentially moving the substrate in line through the different stations, and wherein the second station includes a structure for separately positioning at least three different donor elements in material transferring relationship with the substrate to form different emissive layers on the substrate.

10. The method of claim 8 further including providing a fifth station in the controlled environment for encapsulating the OLED device after step g).

11. The method of claim 8 further including providing a fifth station for pretreating the substrate prior to step a).

12. The method of claim 8 wherein the first station includes a first vacuum chamber and a structure for applying a hole-transporting material over the substrate.

13. The method of claim 8 wherein the third station includes a second vacuum chamber and a structure for applying an electron-transporting material over the emissive layer.

14. The method of claim 8 wherein the first station includes a first cluster of controlled atmosphere coaters and the one or more robots selectively positions the substrate in the appropriate controlled atmosphere coater.

15. The method of claim 14 wherein the third station is either a second cluster of controlled atmosphere coaters or is included in the first cluster.

16. The method of claim 8 further including a unitary housing encompassing the first, second, third, and fourth stations and the robots, and having the controlled atmosphere.

17. A system for making, in a controlled environment, an OLED device comprising:
a) means for positioning a substrate having an electrode in a first station and coating one or more first organic layer(s) over the substrate;
b) first actuable robot control means effective when actuated for grasping and removing the substrate from the first station and positioning the coated substrate into a second station, in material transferring relationship with a donor element that includes emissive organic material;
c) actuable radiation means effective when actuated for applying radiation to the donor element to selectively transfer organic material from the donor element to the substrate to form an emissive layer on the coated substrate;
d) second actuable robot control means effective when actuated for grasping and removing the emissive coated substrate from the second station and positioning the emissive coated substrate in a third station, and coating means effective when actuated for coating one or more second organic layers over the emissive layer coated substrate;
e) third actuable robot control means effective when actuated for grasping and removing such emissive coated substrate from the third station, and positioning the emissive coated substrate in a fourth station;
f) means for forming a second electrode over the one or more second organic layers of the emissive coated substrate; and
g) process control means for controlling in a time sequence the actuation of the first, second, and third coating means and the actuable robot control means, and the actuable radiation means; and
h) means for controlling the atmosphere in the first, second, third, and fourth stations and in which the robot(s) operate so that the water vapor partial pressure is less than 1 torr but greater than 0 torr, or the oxygen partial pressure is less than 1 torr but greater than 0 torr, or both the water vapor partial pressure and the oxygen partial pressure are respectively less than 1 torr but greater than 0 torr.
